(19) United States
(12) Patent Application Publication
(10) Pub. No.: US 2023/0043886 A1
(43) Pub. Date: Feb. 9, 2023

(54) EPITAXIAL WAFER, PREPARING METHOD THEREOF, AND LIGHT-EMITTING DEVICE

(71) Applicant: CHONGQING KONKA PHOTOELECTRIC TECHNOLOGY RESEARCH INSTITUTE CO., LTD., Chongqing (CN)

(72) Inventor: Yang ZHANG, Chongqing (CN)

(21) Appl. No.: 17/971,206

(22) Filed: Oct. 21, 2022

Related U.S. Application Data
(63) Continuation of application No. PCT/CN2021/107929, filed on Jul. 22, 2021.

(51) Int. Cl. H01L 33/38; H01L 33/00

(52) U.S. Cl. CPC H01L 33/382; H01L 33/005; H01L 2933/0016

(57) ABSTRACT

The present disclosure relates to an epitaxial wafer and a preparing method thereof, and a light-emitting device. The epitaxial wafer includes a substrate and an epitaxial stack, the epitaxial stack is disposed on the substrate, and the epitaxial stack includes a first epitaxial structure, a conductive adhesive layer, and a second epitaxial structure which are sequentially stacked in a direction parallel to an extension direction of the substrate. The first epitaxial structure is adhesively fixed to the second epitaxial structure through the conductive adhesive layer. The first epitaxial structure includes a first N-type semiconductor layer, a first active layer, and a first P-type semiconductor layer. The second epitaxial structure includes a second N-type semiconductor layer, a second active layer, and a second P-type semiconductor layer.

### CROSS-REFERENCE TO RELATED APPLICATIONS

This application is a continuation of International Application No. PCT/CN2021/107929, filed Jul. 22, 2021, the entire disclosure of which is incorporated herein by reference.

### TECHNICAL FIELD

This disclosure relates to the field of display, and in particular to an epitaxial wafer and a preparing method thereof, and a light-emitting device.

### BACKGROUND

Light emitting diodes (LEDs) have advantages of wide color gamut, high brightness, large viewing angles, low power consumptions, long service life, etc. Therefore, a LED is widely used in a display field. For example, the LED is commonly used in information display of security exchange and finance, information display of airport flight dynamics, passenger guidance information display at ports and stations, information display at stadiums, information display of road traffic, information display at dispatching command centers such as power dispatching, vehicle dynamic tracking, etc., information display of business publicity of shopping malls and other service areas, advertising media products, etc.

Light-emitting brightness of the LED depends on its light-emitting efficiency. Due to absorption of a light or change of a polarization characteristic of an existing LED, light extraction efficiency is relatively low, such that the light-emitting efficiency is also relatively low, which seriously affects an amount of light output from the front of the LED, thereby resulting in unsatisfactory brightness of the LED.

Therefore, how to improve the light extraction efficiency, so as to improve the light-emitting efficiency and improve the light-emitting brightness of the LED, is an urgent problem to be solved.

### SUMMARY

At a first aspect, an epitaxial wafer is provided in the present disclosure. The epitaxial wafer includes a substrate and an epitaxial stack. The epitaxial stack is disposed on the substrate. The epitaxial stack includes a first epitaxial structure, a conductive adhesive layer, and a second epitaxial structure which are sequentially stacked in a direction parallel to an extension direction of the substrate. The first epitaxial structure is adhesively fixed to the second epitaxial structure through the conductive adhesive layer. The first epitaxial structure includes a first N-type semiconductor layer, a first active layer, and a first P-type semiconductor layer which are sequentially stacked in the direction parallel to the extension direction of the substrate. The second epitaxial structure includes a second N-type semiconductor layer, a second active layer, and a second P-type semiconductor layer which are sequentially stacked in the direction parallel to the extension direction of the substrate.

At a second aspect, a light-emitting device is provided in the present disclosure. The light-emitting device includes an epitaxial wafer, a P-side electrode layer, and a N-side electrode layer. The epitaxial wafer includes a substrate and an epitaxial stack. The epitaxial stack is disposed on the substrate. The epitaxial stack includes a first epitaxial structure, a conductive adhesive layer, and a second epitaxial structure which are sequentially stacked in a direction parallel to an extension direction of the substrate. The first epitaxial structure is adhesively fixed to the second epitaxial structure through the conductive adhesive layer. The first epitaxial structure includes a first N-type semiconductor layer, a first active layer, and a first P-type semiconductor layer which are sequentially stacked in the direction parallel to the extension direction of the substrate. The second epitaxial structure includes a second N-type semiconductor layer, a second active layer, and a second P-type semiconductor layer which are sequentially stacked in the direction parallel to the extension direction of the substrate. The epitaxial stack has a first surface and a second surface which are arranged opposite to each other in a growth direction of the epitaxial wafer. The P-side electrode layer is disposed on the first surface and is stacked on at least part of the first P-type semiconductor layer, the conductive adhesive layer, and at least part of the second P-type semiconductor layer. The N-side electrode layer is disposed on the second surface and is stacked on at least part of the first N-type semiconductor layer and at least part of the second N-type semiconductor layer. The light-emitting device is provided with the above epitaxial wafer, so the light extraction efficiency is significantly improved and the light output efficiency is improved. The P-side electrode layer and the N-side electrode layer are disposed on two different surfaces, which can make currents distribute on two sides, so as to increase an effective area of composite radiation.

At a third aspect, a preparing method of an epitaxial wafer is provided in the present disclosure, and can be specifically used to prepare the epitaxial wafer of any one of the first aspect in the present disclosure. The method specifically includes following steps. A first epitaxial structure and a second epitaxial structure are provided. The first epitaxial structure includes a first N-type semiconductor layer, a first active layer, and a first P-type semiconductor layer which are sequentially stacked, and the second epitaxial structure includes a second N-type semiconductor layer, a second active layer, and a second P-type semiconductor layer which are sequentially stacked. The first epitaxial structure is adhered to the second epitaxial structure through a conductive adhesive layer to form an epitaxial module. The epitaxial module is patterned to divide the epitaxial module into multiple epitaxial stacks. An epitaxial stack is transferred onto a substrate. A stacked direction of the first epitaxial structure, the conductive adhesive layer, and the second epitaxial structure in a transferred epitaxial stack is parallel to an extension direction of the substrate.

### BRIEF DESCRIPTION OF THE DRAWINGS

FIG. 1 is a schematic structural diagram of an epitaxial wafer in the related art.

FIG. 2 is a schematic structural diagram of an epitaxial wafer provided in an implementation of the present disclosure.

FIG. 3 is a schematic diagram of a light-emitting mode of the epitaxial wafer illustrated in FIG. 2.

FIG. 4 is a schematic structural diagram of an epitaxial wafer provided in another implementation of the present disclosure.

FIG. 5 is a schematic structural diagram of an epitaxial wafer provided in yet another implementation of the present disclosure.

FIG. 6 is a schematic structural diagram of a light-emitting device provided in an implementation of the present disclosure.

FIG. 7 is a schematic diagram of current distribution of the light-emitting device illustrated in FIG. 6.

FIG. 8 is a schematic structural diagram of a light-emitting device provided in another implementation of the present disclosure.

FIG. 9 is a schematic structural diagram of a light-emitting device provided in yet another implementation of the present disclosure.

FIG. 10 is a schematic structural diagram of a light-emitting device provided in yet another implementation of the present disclosure.

FIG. 11 is a schematic structural diagram of a light-emitting device provided in yet another implementation of the present disclosure.

FIG. 12 to FIG. 15 are schematic diagrams of a preparation process of the epitaxial wafer illustrated in FIG. 2.

FIG. 16 to FIG. 25 are schematic diagrams of a preparation process of the light-emitting device illustrated in FIG. 9.

Description of reference signs:

The related art: 1-P-type semiconductor layer, 2-active layer, 3-N-type semiconductor layer.

The present disclosure: 100-epitaxial stack, 150-first surface, 160-second surface, 110-first epitaxial structure, 111-first N-type semiconductor layer, 112-first active layer, 113-first P-type semiconductor layer, 120-second epitaxial structure, 121-second N-type semiconductor layer, 122-second active layer, 123-second P-type semiconductor layer, 130-conductive adhesive layer, 131-first conductive adhesive layer,132-second conductive adhesive layer, 200-P-side electrode layer, 210-N-side electrode layer, 300-insulating reflection layer, 400-substrate, 500-first current-diffusion-layer, 510-second current-diffusion-layer, 600-first substrate, 610-second substrate, 700-temporary substrate.

### DETAILED DESCRIPTION

In order to facilitate understanding of the present disclosure, a detailed description will be given with reference to relevant accompanying drawings. The accompanying drawings illustrate some exemplary implementations of the present disclosure. However, the present disclosure can be implemented in many different forms and is not limited to the implementations described herein. On the contrary, these implementations are provided for a more thorough and comprehensive understanding of the present disclosure.

Unless otherwise defined, all technical and scientific terms used herein have the same meaning as commonly understood by those skilled in the art of the present disclosure. The terms used herein in the specification of the present disclosure are for the purpose of describing specific implementations only and are not intended to limit the present disclosure. The “first”, “second”, etc., in the present disclosure are only for convenience of description and cannot be regarded as limitations to the present disclosure.

An epitaxial wafer of a light-emitting diode (LED) can emit a red light, a blue light, a green light, an ultraviolet (UV) light, etc., and a light-emitting color of the epitaxial wafer mainly depends on a material used in an epitaxial process and a doped element. Generally, a common semiconductor material of an infrared LED is indium phosphide (InP), and common semiconductor materials of a red LED are gallium arsenide (GaAs), gallium arsenide aluminum (AlGaAs), gallium arsenide phosphide (GaAsP), and gallium phosphide (GaP), common semiconductor materials of a yellow LED and an orange LED are aluminum gallium indium phosphide (AlGaInP), a common semiconductor material of a green LED is gallium indium nitride (InGaN), a common semiconductor material of a blue LED is gallium indium nitride (InGaN), and a common semiconductor material of an UV LED is gallium aluminum nitride (AlGaN).

The red LED, the green LED, and the blue LED are widely used in a traffic signal lamp, a car signal lamp (a brake lamp and a head lamp), etc. The infrared LED is widely used in a field of communication and sensor, such as a remote controller for a household appliance, a security surveillance camera, a computer mouse, a sensor, etc.

An UV LED based on a wide-bandgap semiconductor material of III-nitride has a broad application prospect in fields of sterilization and disinfection, polymer curing, biochemical detection, non-line-of-sight (NLOS) communication, special lighting, etc. Compared to a traditional UV light source such as a mercury lamp, the UV LED has attracted more and more attention in recent years, since it has many advantages, such as environmental protection without mercury, compactness and portability, low power consumption, low voltage, etc.

No matter what color of a LED, manufacturers and users will pay attention to its light-emitting efficiency, because when the light-emitting efficiency is higher, less energy is consumed, costs are lower, and a scope of application is also wider; and when the light-emitting efficiency is lower, more energy is consumed, the costs are higher, and the scope of application is also reduced. Therefore, improving the light-emitting efficiency is a focus concerned by an industry and a current important development trend.

The light-emitting efficiency of the UV LED is particularly concerned. A AlGaN material is a core material for preparing the UV LED. A AlₓGa₁₋ₓN material is a wide-bandgap and direct-bandgap semiconductor material, and by adjusting an Al component in a ternary compound AlGaN, an energy gap of AlGaN can be continuously changed within 3.4 electronvolts (eV) ~ 6.2 eV, so as to obtain an UV light with a wavelength range from 200 nanometers (nm) to 400 nm. However, light-emitting efficiency of a currently prepared UV LED, especially a deep UV LED, is generally low, which limits wide application of the UV LED.

A main reason for the low light-emitting efficiency of the UV LED is its low light extraction efficiency. A main factor which limits the extraction efficiency of the UV LED is strong absorption of the UV light by P-type GaN, which causes a large amount of light emitted from the front of the UV LED to be absorbed. In addition, with increase of the Al component and decrease of the wavelength, a polarization characteristic of the UV light will change. Specifically, a light-emitting mode will change from mainly a transverse electric (TE) mode in which a light-emitting direction is perpendicular to a growth plane of an active layer to mainly a transverse magnetic (TM) mode in which a light-emitting direction is parallel to the growth plane of the active layer. A propagation direction of a polarized light in the TE mode is perpendicular to the front of the LED, the light easily penetrates through a N-type semiconductor layer (about 3 micrometers (µm)) or a P-type semiconductor layer (about 0.1 µm) which is not thick, and the light is easy to be extracted from the LED. However, a propagation direction of the polarized light in the TM mode is parallel to the front of the LED, and a light propagating in a long path (for a general large-size LED with the size of about 1000 µm* 1000 µm, the light with a horizontal propagation direction generally needs to travel several hundred micrometers to reach a side surface of the LED) near the active layer is easily absorbed by the active layer, which makes it difficult for the light to be extracted from the LED.

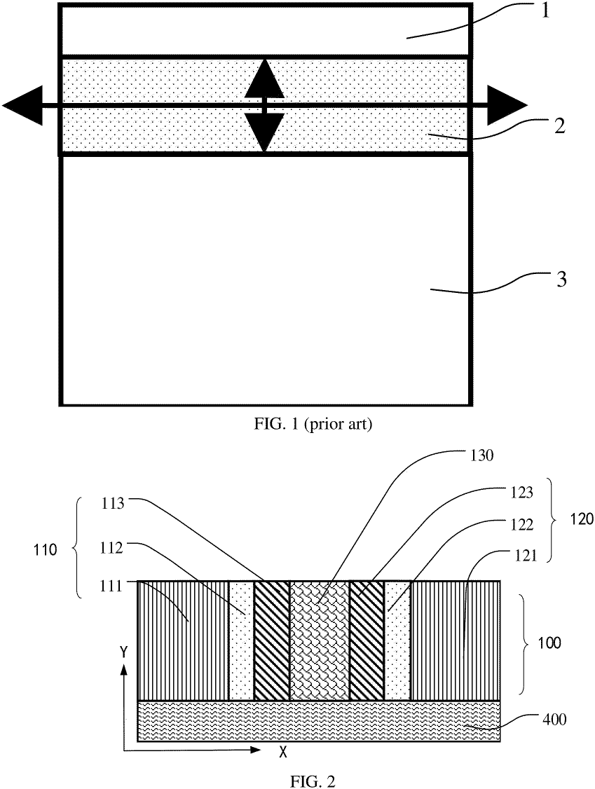

Reference can be made to FIG. 1, which is a schematic structural diagram of an epitaxial wafer in the related art. The epitaxial wafer includes a P-type semiconductor layer 1, an active layer 2, and a N-type semiconductor layer 3 which are stacked from top to bottom. A front light-emitting surface is an upper surface of the P-type semiconductor layer 1. In this case, a propagation direction of a polarized light in the TM mode is parallel to the front light-emitting surface, and a light propagating in a long path near the active layer 2 is easily absorbed by the active layer 2, which makes it difficult for light to be extracted from the LED.

In order to solve a problem of a low extraction rate of the UV LED light, an epitaxial wafer is provided in implementations of the present disclosure. Those skilled in the art can understand that the epitaxial wafer provided in the implementations of the present disclosure can also be applicable to LEDs with other colors to improve light extraction efficiency of the LEDs with other colors, such as a red LED prepared based on AlGaAs, a yellow LED and an orange LED prepared based on AlGaInP, etc.

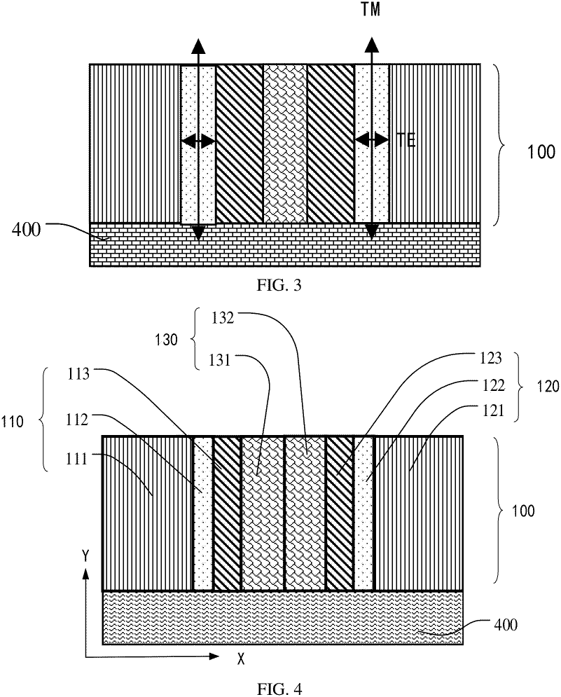

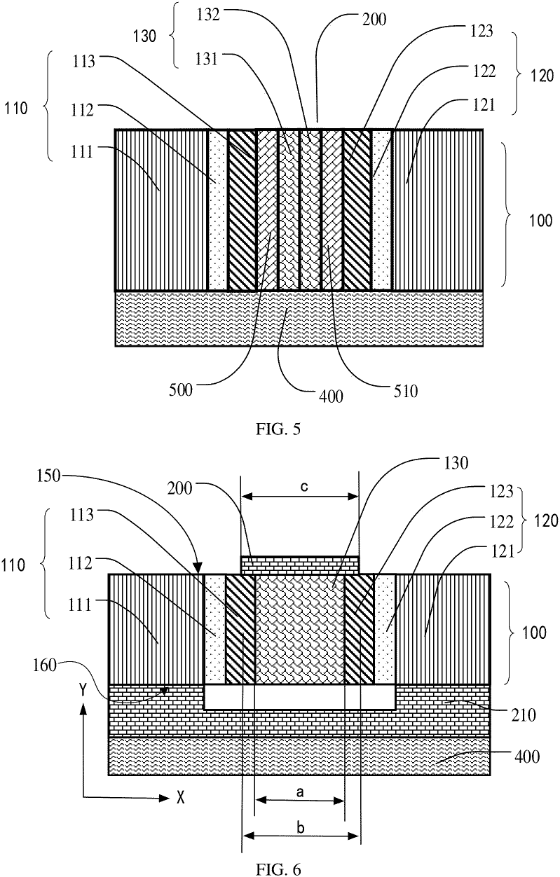

Reference can be made to FIG. 2 and FIG. 3, where FIG. 2 is a schematic structural diagram of an epitaxial wafer provided in an implementation of the present disclosure, and FIG. 3 is a schematic structural diagram of a light-emitting mode of the epitaxial wafer illustrated in FIG. 2. The epitaxial wafer provided in the implementations of the present disclosure includes a substrate 400 and an epitaxial stack 100, the epitaxial stack 100 is disposed on the substrate 400, and the epitaxial stack 100 includes a first epitaxial structure 110, a conductive adhesive layer 130, and a second epitaxial structure 120 which are sequentially stacked in a direction parallel to an extension direction of the substrate 400. The first epitaxial structure 110 is adhesively fixed to the second epitaxial structure 120 through the conductive adhesive layer 130. The first epitaxial structure 110 includes a first N-type semiconductor layer 111, a first active layer 112, and a first P-type semiconductor layer 113 which are sequentially stacked in the direction parallel to the extension direction of the substrate 400. The second epitaxial structure 120 includes a second N-type semiconductor layer 121, a second active layer 122, and a second P-type semiconductor layer 123 which are sequentially stacked in the direction parallel to the extension direction of the substrate 400.

It can be understood that the extension direction X of the substrate 400 is a left-to-right direction illustrated in FIG. 2 or a right-to-left direction illustrated in FIG. 2, and direction Y perpendicular to direction X is a growth direction of the epitaxial wafer. The substrate 400 mainly plays a role in carrying the epitaxial stack 100 of an epitaxial module to increase stability of an epitaxial wafer structure.

In other words, the epitaxial stack 100 includes two epitaxial structures, which has one more epitaxial structure than a traditional LED light-emitting module, so density of the light emitted from the epitaxial wafer is significantly stronger than density of the light emitted from the traditional LED light-emitting module with only one epitaxial structure. Therefore, the light-emitting efficiency is significantly improved.

In addition, the first epitaxial structure 110, the second epitaxial structure 120, inner stacked structures of the first epitaxial structure 110, and inner stacked structures of the second epitaxial structure 120 are all distributed in the direction parallel to the extension direction of the substrate 400, any of two surfaces of the epitaxial stack 100 which are arranged opposite to each other in the growth direction of the epitaxial wafer can be taken as a front light-emitting surface, and the growth direction Y of the epitaxial wafer is perpendicular to the extension direction of the substrate, that is, a bottom-to-top direction in FIG. 3. Reference can be made to FIG. 3, which is a schematic structural diagram of a light-emitting mode of the epitaxial wafer illustrated in FIG. 2. Therefore, even if the Al component is increased in order to increase color depth of an UV light, resulting in the light-emitting mode changes from mainly the TE mode to mainly the TM mode and a propagation direction of a polarized light in the TM mode being perpendicular to the front light-emitting surface in this case, the light is easy to be extracted, which can improve the light extraction efficiency and increase the light output efficiency.

It can be understood that when the LED light-emitting module in the implementations is applicable to the UV LED, a light radiated by the first active layer 112 and the second active layer 122 is the UV light, and a wavelength of the UV light is within 320 nm-400 nm; or within 280 nm-320 nm; or within 200 nm-280 nm.

When the wavelength of the UV light is within 320 nm-400 nm, a radiated light is a long-wave UV light (i.e., UVA); when the wavelength of a radiated UV light is within 280 nm-320 nm, the radiated light is medium-wave UV light (i.e., UVB); and when the wavelength of the radiated UV light is between 200 nm-280 nm, the light radiated is a short-wave UV light (i.e., UVC).

Exemplarily, the first epitaxial structure 110 has a dimension greater than or equal to 0.5 µm and less than or equal to 10 µm in the growth direction of the epitaxial wafer. The second epitaxial structure 120 has a dimension greater than or equal to 0.5 µm and less than or equal to 10 µm in the growth direction of the epitaxial wafer. Therefore, a height of the first epitaxial structure 110 and a height of the second epitaxial structure 120 each are relatively low, so a height of the first active layer 112 and a height of the second active layer 122 are correspondingly low. When the light propagates in the TM mode, propagation time in the first active layer 112 and the second active layer 122 is relatively short, and relatively less light is absorbed, which can improve the light extraction efficiency and increase the light output efficiency.

In some implementations, the first P-type semiconductor layer 113 is opposite to the second N-type semiconductor layer 121, and the first P-type semiconductor layer 113 and the second N-type semiconductor layer 121 are adhesively fixed through the conductive adhesive layer 130. In general, a P-type semiconductor layer has a thickness of about 0.1 µm, a N-type semiconductor layer has a thickness of about 3 µm, that is, the P-type semiconductor layer has a much smaller thickness than the N-type semiconductor layer. Therefore, the first P-type semiconductor layer 113 and the second N-type semiconductor layer 121 are adhered to each other to make the first active layer 112 relatively close to the second active layer 122, such that a light radiated by the first active layer 112 and a light radiated by the second active layer 122 are superimposed, and the light is brighter and more concentrated.

Referring to FIG. 2 and FIG. 3, in other implementations, the first P-type semiconductor layer 113 is opposite to the second P-type semiconductor layer 123, and the first P-type semiconductor layer 113 and the second P-type semiconductor layer 123 are adhesively fixed through the conductive adhesive layer 130. In general, the P-type semiconductor layer has the thickness of about 0.1 µm, the N-type semiconductor layer has the thickness of about 3 µm, that is, the P-type semiconductor layer has the much smaller thickness than the N-type semiconductor layer. Therefore, the first P-type semiconductor layer 113 and the second P-type semiconductor layer 123 are adhered to each other to make the first active layer 112 closer to the second active layer 122, such that the light radiated by the first active layer 112 and the light radiated by the second active layer 122 are superimposed, and the light is brighter and more concentrated.

Exemplarily, a material of the conductive adhesive layer 130 includes a transparent conductive adhesive (TCA). Adoption of the TCA can facilitate passage of the light, which makes the light of the first active layer and the light of the second active layer well superimposed, so as to increase brightness of the light, improve the light extraction efficiency, and increase the light output efficiency. Specifically, the material of the conductive adhesive layer 130 includes an anisotropic conductive film (ACF) or an anisotropic conductive adhesive (ACA). Both the ACA and the ACF have conductive ball particles, so they can conduct electricity. The ACA has a relatively low curing temperature, and an interconnection process is very simple with few process steps, which is conducive to improving production efficiency and reducing costs. The ACF prepared by thermosetting resin such as epoxy resin has advantages of high temperature stability, thermal expansion, low moisture absorption, etc.

Exemplarily, the conductive adhesive layer 130 has a dimension greater than or equal to 0.5 µm and less than or equal to 3 µm in the direction parallel to the extension direction of the substrate 400. When the conductive adhesive layer 130 has the thickness less than 0.5 µm, the conductive adhesive layer 130 may have a relatively weak adhesive force. When the conductive adhesive layer 130 has the thickness greater than 3 µm, the dimension of the whole epitaxial stack 100 will be greatly affected, and superposition of the light of the first active layer 112 and the light of the second active layer 122 will be affected. Therefore, the thickness of the conductive adhesive layer 130 is set within 0.5 µm and 3 µm, which can not only ensure good adhesion of the conductive adhesive layer 130, but also make the thickness of the epitaxial stack 100 as small as possible, and facilitate superposition of the light radiated by the first active layer 112 and the light radiated by the second active layer 122.

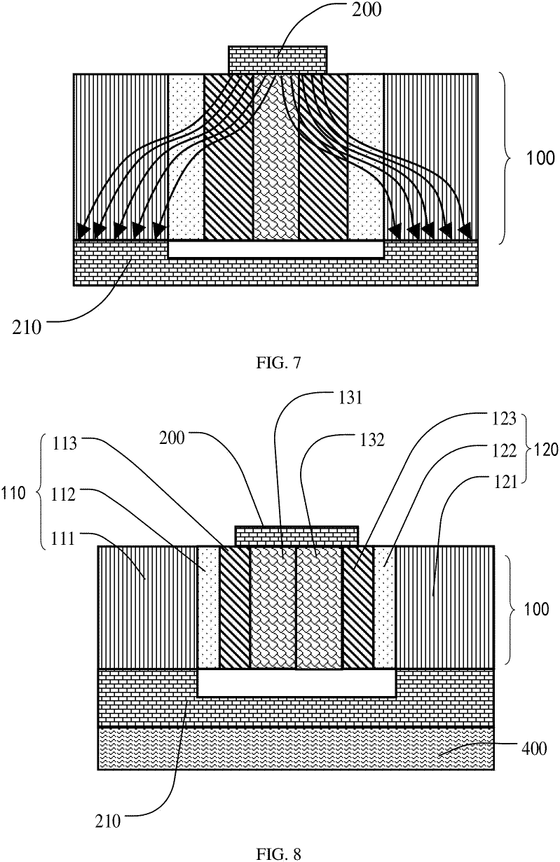

Reference can be made to FIG. 4, which is a schematic structural diagram of an epitaxial wafer provided in another implementation of the present disclosure. In the implementations, the first epitaxial structure 110 and the second epitaxial structure 120 are identical to the above implementations. The difference is that the conductive adhesive layer 130 includes a first conductive adhesive layer 131 and a second conductive adhesive layer 132 adhesively fixed to the first conductive adhesive layer. The first conductive adhesive layer 131 is adhesively fixed to the first P-type semiconductor layer 113, and the second conductive adhesive layer 132 is adhesively fixed to the second P-type semiconductor layer 123. Therefore, before the first epitaxial structure 110 and the second epitaxial structure 120 are adhered to each other, each of the first epitaxial structure 110 and the second epitaxial structure 120 is adhered to a conductive adhesive layer, they have identical structures, which is convenient for processing, and misoperation is not easy to occur during batch processing.

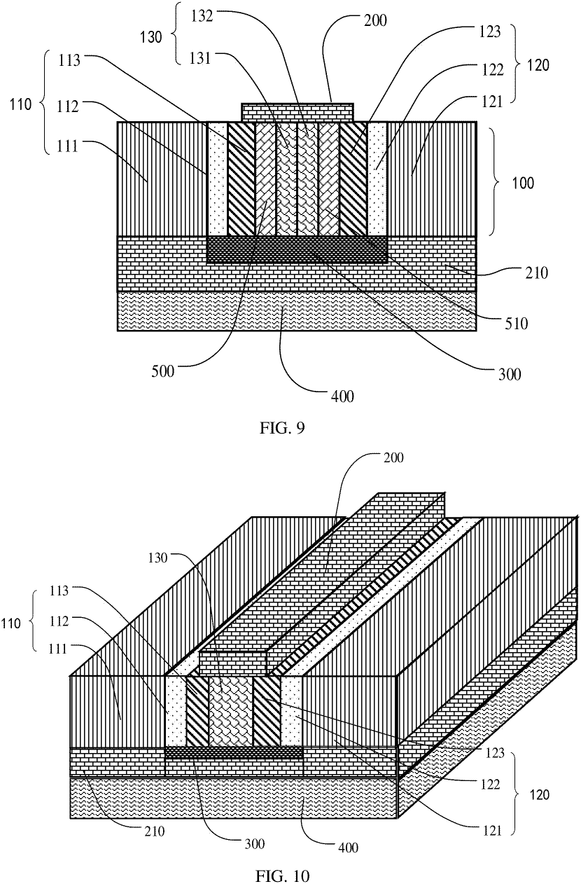

Reference can be made to FIG. 5, which is a schematic structural diagram of an epitaxial wafer provided in yet another implementation of the present disclosure. In the implementations, the epitaxial stack 100 further includes a first current-diffusion-layer 500 and a second current-diffusion-layer 510. The first current-diffusion-layer 500 is stacked between the first P-type semiconductor layer 113 and the conductive adhesive layer 130, and the second current-diffusion-layer 510 is stacked between the second P-type semiconductor layer 123 and the conductive adhesive layer 130. It can be understood that the first current-diffusion-layer 500 and the second current-diffusion-layer 510 each may be indium tin oxides (ITO). The first current-diffusion-layer 500 and the second current-diffusion-layer 510 can improve a current diffusion effect.

Based on the epitaxial wafer provided in the above implementations, a light-emitting device is further provided in some implementations of the present disclosure, and the light-emitting device can be prepared by using the epitaxial wafer provided in the above implementations.

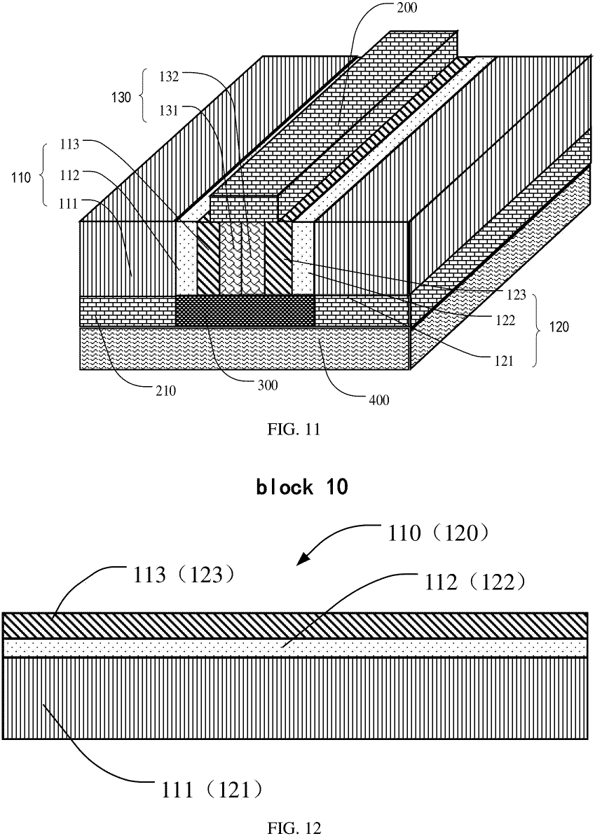

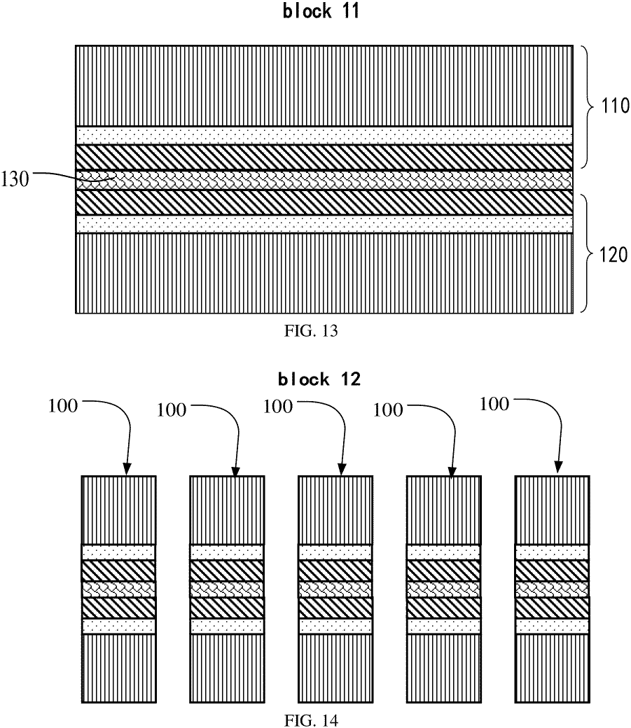

Specifically, reference can be made to FIG. 6, which is a schematic structural diagram of a light-emitting device provided in an implementation of the present disclosure. The light-emitting device includes the epitaxial wafer illustrated in FIG. 2, a P-side electrode layer 200, and a N-side electrode layer 210. The epitaxial stack 100 has a first surface 150 and a second surface 160 which are arranged opposite to each other in the growth direction Y of the epitaxial wafer, and the growth direction of the epitaxial wafer is perpendicular to the extension direction of the substrate 400. The P-side electrode layer 200 is disposed on the first surface 150 and is stacked on at least part of the first P-type semiconductor layer 113, the conductive adhesive layer 130, and at least part of the second P-type semiconductor layer 123. The N-side electrode layer 210 is disposed on the second surface 160 and is stacked on at least part of the first N-type semiconductor layer 111 and at least part of the second N-type semiconductor layer 121. The N-side electrode layer 210 and the P-side electrode layer 200 can facilitate connection between the epitaxial wafer and a driving circuit when the epitaxial wafer is finally used, such that the epitaxial wafer can emit the light successively. Reference can be made to FIG. 7, which is a schematic diagram of current distribution of the light-emitting device illustrated in FIG. 6. The P-side electrode layer 200 and the N-side electrode layer 210 are disposed on two different surfaces, which can make currents distribute on two sides, so as to increase an effective area of composite radiation.

It can be understood that since a distance between the first P-type semiconductor layer 113 and the second P-type semiconductor layer 123 is relatively short, correspondingly, a volume of the P-side electrode layer 200 can be relatively small, such that one side surface where the P-side electrode layer 200 is disposed can be selected as the front light-emitting surface, that is, the above first surface 150 is the front light-emitting surface.

It can be understood that in the implementations, the substrate 400 may be a circuit substrate specifically, so when applied, the substrate 400 can be provided with multiple epitaxial wafers arranged in an array, which can facilitate subsequent preparation of a liquid crystal display and other devices.

Exemplarily, reference can be made to FIG. 6, a dimension of the conductive adhesive layer 130 in the direction parallel to the extension direction of the substrate 400 (that is, direction X in FIG. 6) is a. A dimension between a center of the first P-type semiconductor layer 113 in the direction parallel to the extension direction of the substrate 400 and a center of the second P-type semiconductor layer 123 in the direction parallel to the extension direction of the substrate 400 is b. A dimension of the P-side electrode layer 200 in the direction parallel to the extension direction of the substrate 400 is c and satisfies following conditions: c is greater than a and less than or equal to 0.5b. Therefore, the P-side electrode layer 200 can be in good contact with the first P-type semiconductor layer 113 and the second P-type semiconductor layer 123, and occlusion of the light in the TM mode can also be reduced, thereby improving the light extraction efficiency. In general, the P-side electrode layer 200 is mostly made of metal, so the P-side electrode layer 200 can also reflect the light, thereby increasing the light extraction efficiency and improving the light output efficiency. In addition, the P-side electrode layer can also realize relatively stable current input.

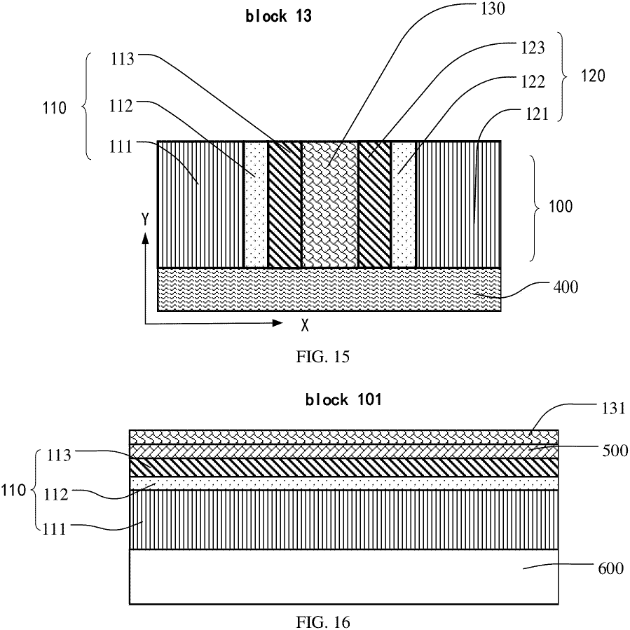

Reference can be made to FIG. 8, which is a schematic structural diagram of a light-emitting device provided in another implementation of the present disclosure. The light-emitting device provided in the implementations includes the epitaxial wafer illustrated in FIG. 4, the P-side electrode layer 200, and N-side electrode layer 210. Specific conditions of the P-side electrode layer 200 and the N-side electrode layer 210 are identical to conditions of the above implementations and will not be repeated.

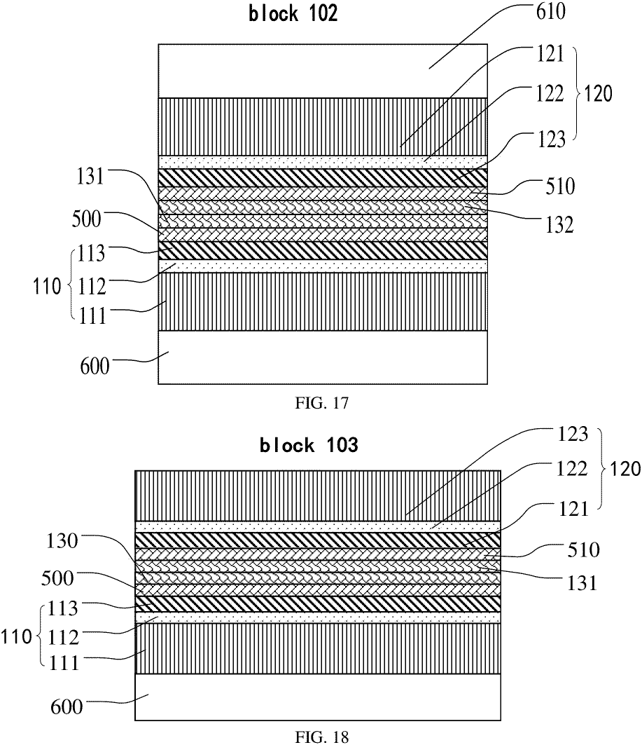

Reference can be made to FIG. 9, which is a schematic structural diagram of a light-emitting device provided in yet another implementation of the present disclosure. The light-emitting device provided in the implementations includes the epitaxial wafer illustrated in FIG. 5, the P-side electrode layer 200, and N-side electrode layer 210. Specific conditions of the P-side electrode layer 200 and the N-side electrode layer 210 are identical to conditions of the above implementations and will not be repeated.

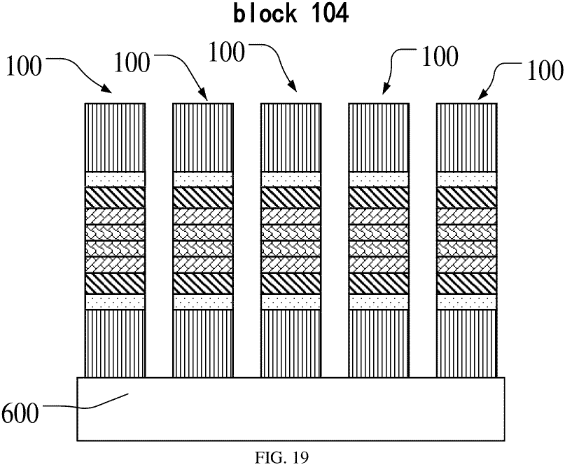

Reference can be made to FIG. 10, which is a schematic structural diagram of a light-emitting device provided in yet another implementation of the present disclosure. In the implementation, the light-emitting device includes the epitaxial wafer illustrated in FIG. 2, the P-side electrode layer 200, and N-side electrode layer 210. Specific conditions of the P-side electrode layer 200 and the N-side electrode layer 210 are identical to conditions of the above implementations and will not be repeated. The difference is that an insulating reflection layer 300 is disposed between the second surface and the N-side electrode layer 210, and covers the first active layer 112, the first P-type semiconductor layer 113, the conductive adhesive layer 130, the second P-type semiconductor layer 123, and the second active layer 122.

In the implementations, the first N-type semiconductor layer 111 and the second N-type semiconductor layer 121 share the N-side electrode layer 210, the N-side electrode layer 210 extends from the first N-type semiconductor layer 111 to the second N-type semiconductor layer 121. Since the first P-type semiconductor layer 113 and the second P-type semiconductor layer 123 are located between the first N-type semiconductor layer 111 and the second N-type semiconductor layer 121, in order to prevent the N-side electrode layer 210 from contacting the first P-type semiconductor layer 113 and/or the second P-type semiconductor layer 123 when extending, the insulating reflection layer 300 is disposed.

The insulating reflection layer 300 separates the N-side electrode layer 210 from the first active layer 112, the first P-type semiconductor layer 113, the conductive adhesive layer 130, the second P-type semiconductor layer 123, and the second active layer 122, which can realize electrical insulation and avoid short circuit. The insulating reflection layer 300 can also reflect the light radiated by the first active layer 112 and the light radiated by the second active layer 122 to the front light-emitting surface, thereby increasing the light extraction efficiency.

The substrate 400 is located on a surface of the N-side electrode layer 210 away from the second surface. The substrate 400 may be made of a conductive material or a non-conductive material. The substrate 400 is made of a high-heat-release material, and the substrate 400 mainly plays a role in carrying the epitaxial stack 100. When preparing the light-emitting device, the substrate 400 may be a circuit substrate, etc.

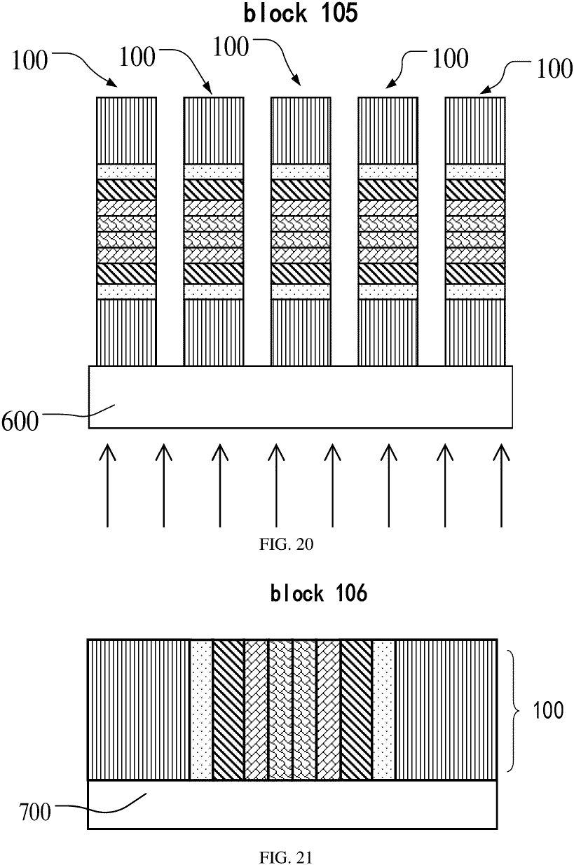

Reference can be made to FIG. 11, which is a schematic structural diagram of a light-emitting device provided in yet another implementation of the present disclosure. In the implementations, the light-emitting device includes the epitaxial wafer illustrated in FIG. 4, the P-side electrode layer 200, N-side electrode layer 210, and the insulating reflection layer 300. The insulating reflection layer 300 and the P-side electrode layer 200 are identical to the above implementations and will not be repeated. The difference is that in the light-emitting device in the implementations, the light-emitting device provided in the implementation includes two N-side electrode layers 210, one N-side electrode layer 210 is stacked on at least part of the first N-type semiconductor layer 111, and another N-side electrode layer 210 is stacked on at least part of the second N-type semiconductor layer 121.

In the implementations, the two N-side electrode layers 210 are disposed, and the two N-side electrode layers 210 are coupled with the first N-type semiconductor layer 111 and the second N-type semiconductor layer 121 respectively, that is, one N-side electrode layer 210 is correspondingly coupled with one N-type semiconductor layer 111 or 121, which can increase coupling stability and alignment accuracy. In addition, the whole extension length of the two N-side electrode layers 210 is relatively short, which is conducive to saving resources.

In this case, the two N-side electrode layers 210 are spaced apart from each other, and the insulating reflection layer 300 can be disposed between the two N-side electrode layers 210. Therefore, a space utilization rate can be improved and a volume of the light-emitting device can be reduced.

It can be understood by those skilled in the art that in some implementations, a buffer layer, a distributed Bragg reflection layer, an electron-blocking layer, an ohmic contact layer, etc., can also be disposed, which will not be repeated in the present disclosure.

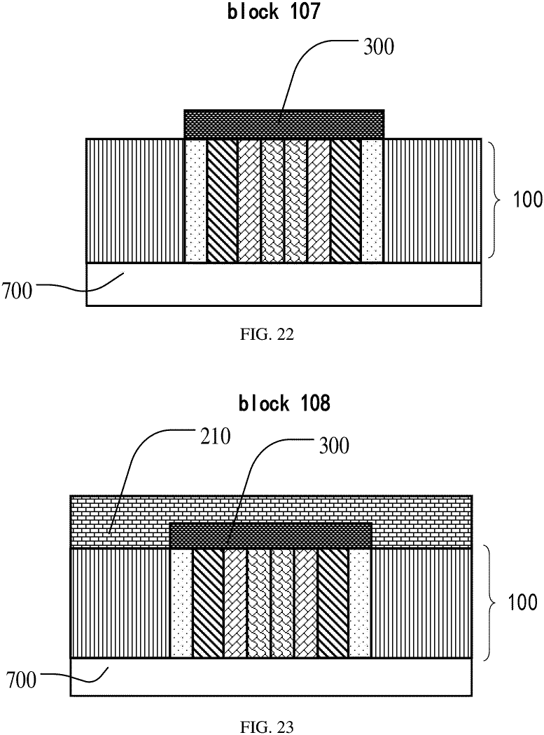

Reference can be made to FIG. 12 to FIG. 15, which are schematic diagrams of a preparation process of the epitaxial wafer illustrated in FIG. 2. Specifically, a preparing method of the epitaxial wafer in FIG. 2 includes following steps. Preparing methods of epitaxial wafers illustrated in FIG. 4 and FIG. 5 can refer to the preparing method of the epitaxial wafer illustrated in FIG. 2, which will not be repeated in the present disclosure.

At block 10, reference can be made to FIG. 12, and the first epitaxial structure 110 and the second epitaxial structure 120 are provided. The first epitaxial structure 110 includes the first N-type semiconductor layer 111, the first active layer 112, and the first P-type semiconductor layer 113 which are sequentially stacked, and the second epitaxial structure 120 includes the second N-type semiconductor layer 121, the second active layer 122, and the second P-type semiconductor layer 123 which are sequentially stacked. The first epitaxial structure 110 and the second epitaxial structure 120 are identical and can be processed in batches.

At block 11, reference can be made to FIG. 13, and the first epitaxial structure 110 is adhered to the second epitaxial structure 120 through the conductive adhesive layer 130 to form an epitaxial module. In this case, the first epitaxial structure 110 and the second epitaxial structure 120 are adhesively fixed as a whole.

At block 12, reference can be made to FIG. 14, and the epitaxial module is patterned to divide the epitaxial module into multiple epitaxial stacks 100.

At block 13, reference can be made to FIG. 15, and an epitaxial stack 100 is transferred onto the substrate 400. A stacked direction of the first epitaxial structure 110, the conductive adhesive layer 130, and the second epitaxial structure 120 in a transferred epitaxial stack 100 is parallel to the extension direction of the substrate 400.

Density of the light emitted from the epitaxial wafer prepared by the method is significantly stronger than density of the light emitted from the traditional LED light-emitting module with only one epitaxial structure. Therefore, the light-emitting efficiency is significantly improved.

In addition, the first epitaxial structure 110, the second epitaxial structure 120, inner stacked structures of the first epitaxial structure 110, and inner stacked structures of the second epitaxial structure 120 are all distributed in the direction parallel to the extension direction of the substrate, and any of two surfaces of the epitaxial stack 100 which are arranged opposite to each other in the growth direction of the epitaxial wafer can be taken as the front light-emitting surface 400. Therefore, even if the Al component is increased in order to increase color depth of the UV light, resulting in the light-emitting mode changing from mainly the TE mode to mainly the TM mode and the propagation direction of the polarized light in the TM mode being perpendicular to the front light-emitting surface in this case, the light is easy to be extracted, which can improve the light extraction efficiency and increase the light output efficiency.

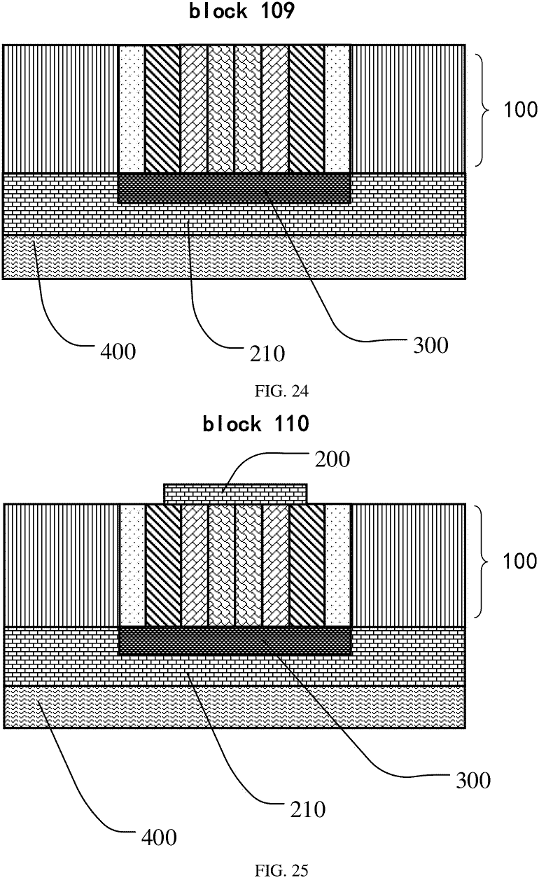

Reference can be made to FIG. 16 to FIG. 25, which are schematic diagrams of a preparation process of the light-emitting device illustrated in FIG. 9, and specific steps are as follows. Preparation processes of the light-emitting devices in other implementations can refer to the preparation process of the light-emitting device in FIG. 9, which will not be repeated in the present disclosure.

At block 101, reference can be made to FIG. 16, the first epitaxial structure 110 provided with the first conductive adhesive layer 131 is provided, and the second epitaxial structure 120 provided with the second conductive adhesive layer 132 is provided. The first epitaxial structure 110 grows on a first substrate 600 and the second epitaxial structure 120 grows on a second substrate 610. FIG. 16 illustrates a schematic diagram of the first epitaxial structure 110, and the second epitaxial structure 120 is identical to the first epitaxial structure 110 and not shown in FIG. 16.

Specifically, the first epitaxial structure 110 includes the first N-type semiconductor layer 111, the first active layer 112, the first P-type semiconductor layer 113, and the first current-diffusion-layer 500 which are sequentially stacked, and the first conductive adhesive layer 131 is adhered to the first current-diffusion-layer 500. The second epitaxial structure 120 includes the second N-type semiconductor layer 121, the second active layer 122, the second P-type semiconductor layer 123, and the second current-diffusion-layer 510 which are sequentially stacked, and the second conductive adhesive layer is adhered to the second current-diffusion-layer 510.

At block 102, reference can be made to FIG. 17, and the first conductive adhesive layer is adhesively fixed to the second conductive adhesive layer, such that the first epitaxial structure 110 and the second epitaxial structure 120 are adhesively fixed as a whole.

At block 103, reference can be made to FIG. 18, and the second substrate 610 of the second epitaxial structure 120 is lifted off. Specifically, laser lift off (LLO) can be adopted.

At block 104, reference can be made to FIG. 19, and the whole structure adhered by the first epitaxial structure 110 and the second epitaxial structure 120 is patterned. In this case, the whole structure is separated into multiple epitaxial stacks 100.

At block 105, reference can be made to FIG. 20, and some epitaxial stacks 100 are selectively lifted off. Specifically, the first substrate 600 can be selectively irradiated with the laser to lift off corresponding epitaxial stacks 100.

At block 106, reference can be made to FIG. 21, and an epitaxial stack 100 lifted off is transferred to a temporary storage substrate 700.

At block 107, reference can be made to FIG. 22, and the insulating reflection layer 300 is prepared on a surface of the epitaxial stack 100 away from the temporary storage substrate 700, that is, on the above second surface.

At block 108, reference can be made to FIG. 23, and the N-side electrode layer 210 is prepared on the second surface of the epitaxial stack 100. The insulating reflection layer 300 is located between the second surface and the N-side electrode layer 210, and covers the first active layer 112, the first P-type semiconductor layer 113, the conductive adhesive layer 130, the second P-type semiconductor layer 123, and the second active layer 122.

At block 109, reference can be made to FIG. 24, the substrate 400 is prepared on the N-side electrode layer 210, and then the temporary storage substrate 700 is lifted off.

At block 110, reference can be made to FIG. 25, and the P-side electrode layer 200 is prepared on the first surface of the epitaxial stack 100.

The light-emitting device prepared by the above method includes two epitaxial structures, which has one more epitaxial structure than the traditional LED light-emitting module, so density of the light emitted from the epitaxial wafer is significantly stronger than density of the light emitted from the traditional LED light-emitting module with only one epitaxial structure. Therefore, the light-emitting efficiency is significantly improved. In addition, even if the Al component is increased in order to increase color depth of an UV light, resulting in the light-emitting mode changing from mainly the TE mode to mainly the TM mode and the propagation direction of the polarized light in the TM mode being perpendicular to the front light-emitting surface in this case, the light is easy to be extracted, which can improve the light extraction efficiency and increase the light output efficiency.

It can be understood that after block 106 and before block 107, block 1071 can also be included. At block 1071, surface texturing is performed on each surface of the epitaxial stack 100 except a surface of the epitaxial stack 100 in contact with the temporary storage substrate 700. Therefore, the light output efficiency can be improved.

It can also be understood that after block 107 and before block 108, block 1081 can also be included. At block 1081, the ohmic contact layer is disposed by chemical vapor deposition (CVD) or physical vapor deposition (PVD).

A display device is further provided in the implementations of the present disclosure and includes the light-emitting device of any of implementations in the present disclosure. In the present disclosure, the display device may be a display device with a display effect and/or a touch effect, such as a mobile phone, a tablet computer, a notebook computer, etc., which is not specifically limited.

It should be understood that the application of the present disclosure is not limited to the above examples, and for those of ordinary skill in the art, improvements or modifications can be made according to the above descriptions, and all such improvements and modifications shall fall within the protection scope of the appended claims of the present disclosure.

What is claimed is:

1. An epitaxial wafer, comprising:
a substrate; and
an epitaxial stack disposed on the substrate, wherein,
the epitaxial stack comprises a first epitaxial structure, a conductive adhesive layer, and a second epitaxial structure which are sequentially stacked in a direction parallel to an extension direction of the substrate; the first epitaxial structure is adhesively fixed to the second epitaxial structure through the conductive adhesive layer;
the first epitaxial structure comprises a first N-type semiconductor layer, a first active layer, and a first P-type semiconductor layer which are sequentially stacked in the direction parallel to the extension direction of the substrate; and
the second epitaxial structure comprises a second N-type semiconductor layer, a second active layer, and a second P-type semiconductor layer which are sequentially stacked in the direction parallel to the extension direction of the substrate.

2. The epitaxial wafer of claim 1, wherein the first P-type semiconductor layer is opposite to the second P-type semiconductor layer, and the first P-type semiconductor layer and the second P-type semiconductor layer are adhesively fixed through the conductive adhesive layer.

3. The epitaxial wafer of claim 1, wherein the first P-type semiconductor layer is opposite to the second N-type semiconductor layer, and the first P-type semiconductor layer and the second N-type semiconductor layer are adhesively fixed through the conductive adhesive layer.

4. The epitaxial wafer of claim 1, wherein a material of the conductive adhesive layer comprises a transparent conductive adhesive (TCA).

5. The epitaxial wafer of claim 4, wherein the material of the conductive adhesive layer comprises an anisotropic conductive film (ACF) or an anisotropic conductive adhesive (ACA).

6. The epitaxial wafer of claim 1, wherein the conductive adhesive layer has a dimension greater than or equal to 0.5 micrometers (µm) and less than or equal to 3 µm in the direction parallel to the extension direction of the substrate.

7. The epitaxial wafer of claim 1, wherein the conductive adhesive layer comprises a first conductive adhesive layer and a second conductive adhesive layer adhesively fixed to the first conductive adhesive layer, the first conductive adhesive layer is adhesively fixed to the first epitaxial structure, and the second conductive adhesive layer is adhesively fixed to the second epitaxial structure.

8. The epitaxial wafer of claim 1, wherein the first epitaxial structure has a dimension greater than or equal to 0.5 µm and less than or equal to 10 µm in a growth direction of the epitaxial wafer, and the second epitaxial structure has a dimension greater than or equal to 0.5 µm and less than or equal to 10 µm in the growth direction of the epitaxial wafer.

9. The epitaxial wafer of claim 1, wherein the epitaxial stack further comprises a first current-diffusion-layer and a second current-diffusion-layer, the first current-diffusion-layer is stacked between the first P-type semiconductor layer and the conductive adhesive layer, and the second current-diffusion-layer is stacked between the second P-type semiconductor layer and the conductive adhesive layer.

10. A light-emitting device, comprising:
an epitaxial wafer comprising:
a substrate; and
an epitaxial stack disposed on the substrate, wherein,
the epitaxial stack comprises a first epitaxial structure, a conductive adhesive layer, and a second epitaxial structure which are sequentially stacked in a direction parallel to an extension direction of the substrate; the first epitaxial structure is adhesively fixed to the second epitaxial structure through the conductive adhesive layer;
the first epitaxial structure comprises a first N-type semiconductor layer, a first active layer, and a first P-type semiconductor layer which are sequentially stacked in the direction parallel to the extension direction of the substrate; and
the second epitaxial structure comprises a second N-type semiconductor layer, a second active layer, and a second P-type semiconductor layer which are sequentially stacked in the direction parallel to the extension direction of the substrate;
a P-side electrode layer; and
a N-side electrode layer, wherein
the epitaxial stack has a first surface and a second surface which are arranged opposite to each other in a growth direction of the epitaxial wafer, the P-side electrode layer is disposed on the first surface and is stacked on at least part of the first P-type semiconductor layer, the conductive adhesive layer, and at least part of the second P-type semiconductor layer, and the N-side electrode layer is disposed on the second surface and is stacked on at least part of the first N-type semiconductor layer and at least part of the second N-type semiconductor layer.

11. The light-emitting device of claim 10, further comprising:
a plurality of epitaxial wafers arranged on the substrate in an array.

12. The light-emitting device of claim 10, wherein a dimension of the conductive adhesive layer in the direction parallel to the extension direction of the substrate is a;
a dimension between a center of the first P-type semiconductor layer in the direction parallel to the extension direction of the substrate and a center of the second P-type semiconductor layer in the direction parallel to the extension direction of the substrate is b; and
a dimension of the P-side electrode layer in the direction parallel to the extension direction of the substrate is c and satisfies following conditions:
c is greater than a and less than or equal to 0.5b.

13. The light-emitting device of claim 10, further comprising:
an insulating reflection layer disposed on the second surface and covering the first active layer, the first P-type semiconductor layer, the conductive adhesive layer, the second P-type semiconductor layer, and the second active layer.

14. The light-emitting device of claim 10, wherein the N-side electrode layer is implemented as two N-side electrode layers, one N-side electrode layer is stacked on at least part of the first N-type semiconductor layer, and another N-side electrode layer is stacked on at least part of the second N-type semiconductor layer.

15. The light-emitting device of claim 10, wherein the first P-type semiconductor layer is opposite to the second P-type semiconductor layer, and the first P-type semiconductor layer and the second P-type semiconductor layer are adhesively fixed through the conductive adhesive layer.

16. The light-emitting device of claim 10, wherein the first P-type semiconductor layer is opposite to the second N-type semiconductor layer, and the first P-type semiconductor layer and the second N-type semiconductor layer are adhesively fixed through the conductive adhesive layer.

17. The light-emitting device of claim 10, wherein a material of the conductive adhesive layer comprises a transparent conductive adhesive (TCA).

18. The light-emitting device of claim 10, wherein the conductive adhesive layer comprises a first conductive adhesive layer and a second conductive adhesive layer adhesively fixed to the first conductive adhesive layer, the first conductive adhesive layer is adhesively fixed to the first epitaxial structure, and the second conductive adhesive layer is adhesively fixed to the second epitaxial structure.

19. The light-emitting device of claim 10, wherein the epitaxial stack further comprises a first current-diffusion-layer and a second current-diffusion-layer, the first current-diffusion-layer is stacked between the first P-type semiconductor layer and the conductive adhesive layer, and the second current-diffusion-layer is stacked between the second P-type semiconductor layer and the conductive adhesive layer.

20. A preparing method of an epitaxial wafer, comprising:
providing a first epitaxial structure and a second epitaxial structure, wherein the first epitaxial structure comprises a first N-type semiconductor layer, a first active layer, and a first P-type semiconductor layer which are sequentially stacked, and the second epitaxial structure comprises a second N-type semiconductor layer, a second active layer, and a second P-type semiconductor layer which are sequentially stacked;
adhering the first epitaxial structure to the second epitaxial structure through a conductive adhesive layer to form an epitaxial module;
patterning the epitaxial module to divide the epitaxial module into a plurality of epitaxial stacks; and
transferring an epitaxial stack onto a substrate, wherein a stacked direction of the first epitaxial structure, the conductive adhesive layer, and the second epitaxial structure in a transferred epitaxial stack is parallel to an extension direction of the substrate.
